(19) United States
(12) Patent Application Publication
(10) Pub. No.: US 2014/0339130 A1
(43) Pub. Date: Nov. 20, 2014

(54) Apparatus for Protecting Electronic Devices and Methods of Making and Using the Same

(71) Applicants: Patrick Kieran Manning, Santa Cruz, CA (US); Katherin Emilia Robbins, San Francisco, CA (US)

(72) Inventors: Patrick Kieran Manning, Santa Cruz, CA (US); Katherin Emilia Robbins, San Francisco, CA (US)

(21) Appl. No.: 14/215,248

(22) Filed: Mar. 17, 2014

Related U.S. Application Data
(60) Provisional application No. 61/793,846, filed on Mar. 15, 2013.

(51) Int. Cl. H05K 7/12

(52) U.S. Cl. CPC H05K 7/12
USPC 206/586

(57) ABSTRACT

The present invention relates to an apparatus for protecting electronic devices from excessive drops. Specifically, the apparatus is designed to protect iPhones, iPads, iPods, or similar electronic devices. More specifically, the apparatus is made from thermoplastic polyurethane that surrounds the electronic device. The thermoplastic polyurethane includes an energy absorbing material such as, for example, PORON® urethane foam adhered thereon by a pressure sensitive adhesive. Furthermore, the electronic device is protected from scratching by a soft fabric.

The present invention claims priority under 35 U.S.C. §119(d) to U.S. Provisional Patent Application No. 61/793,846, titled “Apparatus for Protecting Electronic Devices and Methods of Making and Using the Same,” filed Mar. 15, 2013, which is incorporated herein by reference in its entirety.

### TECHNICAL FIELD

The present invention relates to an apparatus for protecting electronic devices from excessive drops. Specifically, the apparatus is designed to protect iPhones, iPads, iPods, or similar electronic devices. More specifically, the apparatus is made from thermoplastic polyurethane that surrounds the electronic device. The thermoplastic polyurethane includes an energy absorbing foam or gel adhered thereon by a pressure sensitive adhesive. Furthermore, the electronic device is protected from scratching by a soft fabric disposed over the foam or gel in contact with the electronic device.

### BACKGROUND

It is, of course, generally known to use electronic devices. Indeed, in this modern age, it is common to see individuals using portable electronic devices for communication, reading email, surfing the internet, keeping a calendar and for other computing tasks. Electronic devices contain internal circuitry and typically glass screens that are extremely fragile. Breaking internal circuitry and/or screens can cause an electronic device to cease functions and become useless.

Generally, a shell surrounds the internal circuitry of an electronic device. Shells are generally made from rigid material, such as metal or plastic that prevents the internal circuitry from being exposed to weather, bending, twisting, and many other dangers.

Electronic devices have become smaller and smaller for both performance and aesthetical reasons. As the electronic devices get smaller, less and less room is available inside the electronic device shell. Normally, any internal circuitry extends to the inner wall of the surrounding shell, leaving no room for great amounts of shock absorption. This leaves the internal circuitry of electronic devices exposed to drops, smashing, shaking, or other forceful actions.

Frequently, the internal circuitry of an electronic device breaks when the electronic device drops. In SquareTrade's November 2010 Smart Phone Reliability report, drops were the cause of 77% of all accidental damage to the smart phones. The velocity at the time of impact, or the impact velocity, is generally directly proportional to damage. The rapid deceleration of the impact velocity creates an impact energy that is otherwise transferred directly to an electronic device. Typically, when an electronic device drops, there is nothing to slow down or impede that rapid deceleration.

Commonly, adding shock absorption inside an electronic device shell makes the electronic device more bulky, leaves less room for internal circuitry, and fails to protect the electronic device shell or screen. While an electronic device shell is created to protect the internal circuitry, they are also created to be aesthetically pleasing. Scratches, dings, dents, chips, broken buttons, or other damage to the electronic device shell can impede functionality and be aesthetically distasteful and unpleasant.

As noted, electronic device shells have screens to display information to a user. Many times these screens allow a user to interact with the electronic device, such as with touch screen devices. Often, these screens are made of glass or glass-like elements. These screens frequently may crack, shatter, or break entirely rendering the electronic device damaged and/or useless.

It is, of course, generally known to encase electronic devices, shells, and screens. Commonly, the encasement is done for purely aesthetical reasons. Often, the encasement is done for protecting electronic devices, shells, and screens. Many cases are built to resist shock or fall damage, however, cases are typically very limited. These cases are either extremely bulky to withstand excessive drops, or are aesthetically thin but can only withstand relatively small drops.

Generally, bulky cases are displeasing because they are difficult to maneuver, are difficult to store in small places such as a user's pocket, and cause difficulty in using the encased electronic device. Typically, thin cases are displeasing because they offer little protection to the encased electronic device.

One of the bulky cases, from OtterBox®, can withstand 10 foot drops, but weighs 3.91 oz. and has the dimensions 5.52″×2.97″×0.7″. One of the thin cases, from LifeProof®, weighs 1.05 oz. and has the dimensions 5.41″×2.64″×0.6″ but is only rated for drops from 6.6 feet (2 meters).

Previously, most drop resistant cases, whether they were bulky or slim, came in multiple pieces that required disassembly and reassembly around an electronic device. Multiple piece case designs, however, have been generally known to break apart and expose the electronic device to damage.

A need, therefore, exists for apparatuses and methods of making and using to protect electronic devices. Specifically, a need exists for apparatuses and methods of making and using to protect electronic device internal circuitry, shells, and screens.

Moreover, a need exists for apparatuses for protecting portable electronic devices and methods of making and using that is thin and aesthetically pleasing.

Even more specifically, a need exists for apparatuses for protecting portable electronic devices that is lightweight.

In addition, a need exists for apparatuses for protecting portable electronic devices that can withstand extreme stress conditions.

Specifically, a need exists for apparatuses for protecting portable electronic devices that absorb and evenly distribute kinetic energy away from the electronic devices.

More specifically, a need exists for apparatuses for protecting portable electronic devices that have a low deceleration upon impact.

Even more specifically, a need exists for apparatuses for protecting portable electronic devices that safely decelerate impact velocity during a fall.

Further, a need exists for apparatuses for protecting portable electronic devices that can withstand excessive drops.

Even further, a need exists for apparatuses for protecting portable electronic devices that are a singular piece.

### SUMMARY OF THE INVENTION

The present invention relates to an apparatus for protecting electronic devices from excessive drops. Specifically, the apparatus is designed to protect iPhones, iPads, iPods, or similar electronic devices. More specifically, the apparatus is made from thermoplastic polyurethane that surrounds the electronic device. The thermoplastic polyurethane includes PORON(R) urethane foam adhered thereon by a pressure sensitive adhesive. Furthermore, the electronic device is protected from scratching by a soft fabric.

To this end, in an embodiment of the present invention, an apparatus for protecting electronic devices is provided. The apparatus comprises a case for surrounding an electronic device, wherein the case fits tightly around the electronic device, and at least one section of energy absorbing foam or gel, wherein the case and the impact resistant material combine to protect the electronic device from excessive drops.

It is, therefore, an advantage and objective of the present invention to provide for apparatuses and methods of making and using to protect electronic devices.

Specifically, it is an advantage and objective of the present invention to provide apparatuses and methods of making and using to protect electronic device internal circuitry, shells, and screens.

Moreover, it is an advantage and objective of the present invention to provide apparatuses for protecting portable electronic devices and methods of making and using that is thin and aesthetically pleasing.

Even more specifically, it is an advantage and objective of the present invention to provide apparatuses for protecting portable electronic devices that is lightweight.

In addition, it is an advantage and objective of the present invention to provide apparatuses for protecting portable electronic devices that can withstand extreme stress conditions.

Specifically, it is an advantage and objective of the present invention to provide apparatuses for protecting portable electronic devices that absorb and evenly distribute kinetic energy away from the electronic devices.

More specifically, it is an advantage and objective of the present invention to provide apparatuses for protecting portable electronic devices that have a low deceleration upon impact.

Even more specifically, it is an advantage and objective of the present invention to provide apparatuses for protecting portable electronic devices that safely decelerate impact velocity during a fall.

Further, it is an advantage and objective of the present invention to provide apparatuses for protecting portable electronic devices that can withstand excessive drops.

Even further, it is an advantage and objective of the present invention to provide apparatuses for protecting portable electronic devices that are a singular piece.

Additional features and advantages of the present invention are described in, and will be apparent from, the detailed description of the presently preferred embodiments and from the drawings.

### BRIEF DESCRIPTION OF THE DRAWINGS

The drawing figures depict one or more implementations in accord with the present concepts, by way of example only, not by way of limitations. In the figures, like reference numerals refer to the same or similar elements.

FIG. 1 illustrates a perspective view of an apparatus for protecting electronic devices in a preferred embodiment of the present invention.

FIG. 2 illustrates a bottom view of an apparatus for protecting electronic devices in a preferred embodiment of the present invention.

FIG. 3 illustrates a perspective view of an apparatus for protecting electronic devices encasing an electronic device in a preferred embodiment of the present invention.

FIG. 4 illustrates a sectional view of an apparatus for protecting electronic devices encasing an electronic device in a preferred embodiment of the present invention

### DETAILED DESCRIPTION OF THE PRESENTLY PREFERRED EMBODIMENTS

The present invention relates to an apparatus for protecting electronic devices. Specifically, the apparatus is designed to protect iPhones, iPads, iPods, or similar electronic devices. More specifically, the apparatus is made from thermoplastic polyurethane that surrounds the electronic device. The thermoplastic polyurethane includes an energy absorbing material, such as, for example, PORON® urethane foam adhered thereon by a pressure sensitive adhesive. Furthermore, the electronic device is protected from scratching by a soft fabric.

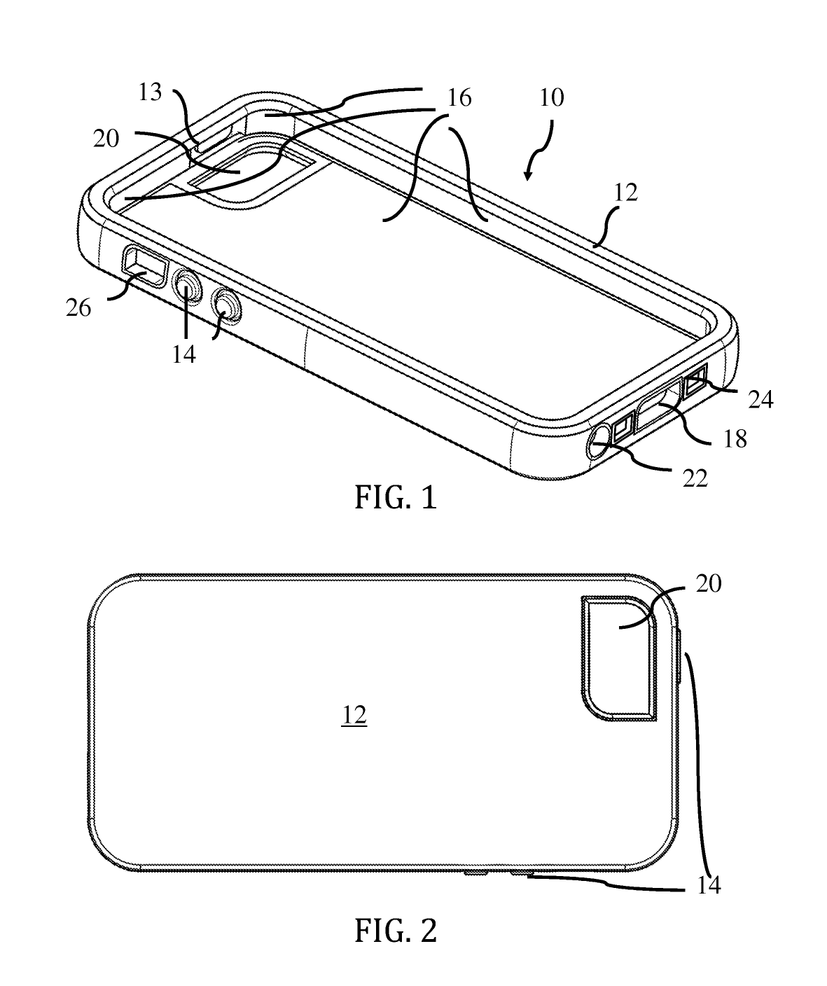

In FIG. 1, an apparatus 10 for protecting electronic devices is shown and described. The apparatus 10 comprises a case 12. The case 12 may comprise four walls and a bottom. As is typical of portable electronic device cases, instead of a top, the case 12 may have a recessed lip 13 sticking inwardly around and a length away from the walls. The recessed lip 13 may also be a length below the apex of the walls. The recessed lip 13 may allow an electronic device to be inserted and held in place by the recessed lip 13.

The front of the electronic device may be protected from damage because the electronic device may be held a length below the apex of the walls, cushioning the front of the electronic device. The case 12 may be formed to allow access to buttons, ports, cameras, screens, or other interactive objects known to one skilled in the art. The case 12 may have buttons 14 formed in the thermoplastic polyurethane that may cover the buttons on an electronic device (not shown). The buttons 14 may be malleable and may be pressed such that contact is made with the buttons on the electronic device (not shown), allowing full interaction with the buttons on the electronic device.

Disposed within the case 12 may be one or a plurality of layers of energy absorbing material 16. The energy absorbing material 16 may be adhered to the case 12 using a pressure sensitive adhesive (not shown). The pressure sensitive adhesive may be any that accomplishes the function described herein, such as, for example, 3M-8626 pressure sensitive adhesive. The apparatus 10 may further comprise a plurality of soft fabric (not shown) that may cover the foam 16 so that an electronic device may be protected from scratches or other damage known to one skilled in the art.

The case 12 may further have a plurality of openings including a cable opening 18, a camera opening 20, a headphone opening 22, a plurality of speaker openings 24, and a button opening 26. The plurality of openings may differ in size for different electronic devices. The plurality of openings may allow access to different parts of the electronic device without hindering the structure of the case 12.

As shown in FIG. 2, the camera opening 20 may be large enough to expose both a camera and a flash on the electronic device. The camera opening 20 may be large enough that the flash is not disrupted when in use. The buttons 14 can be seen in FIG. 2 extending a length away from the case 12.

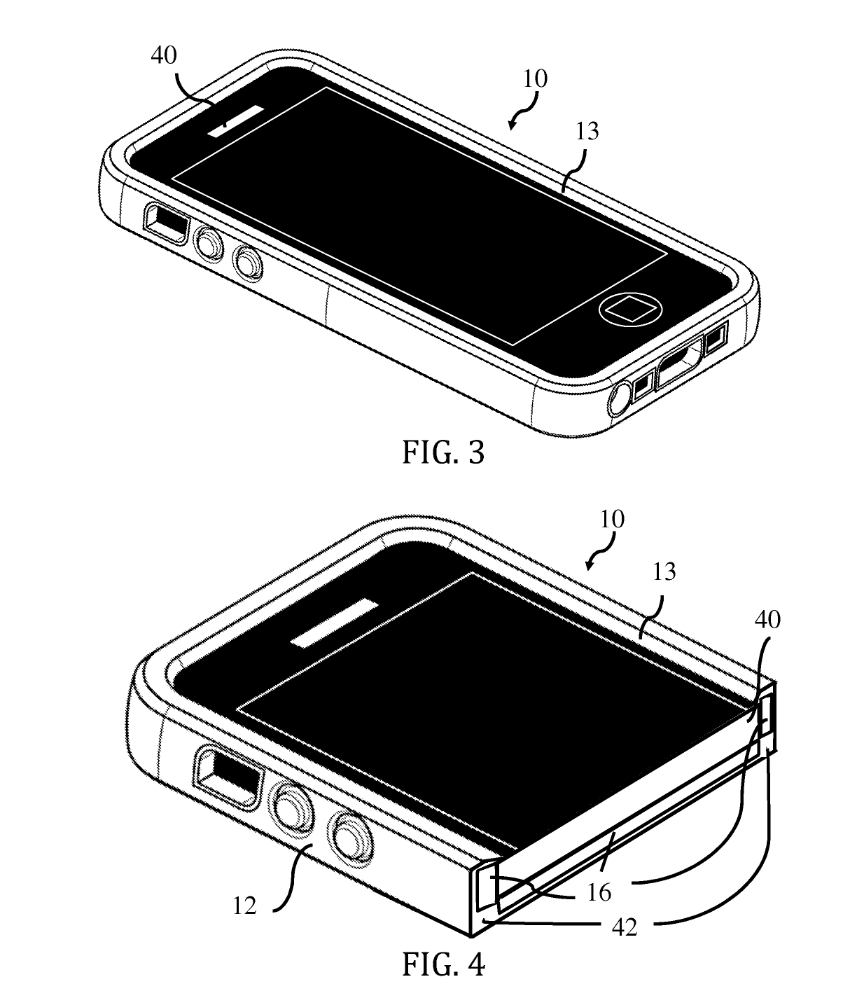

Referring now to FIGS. 3 and 4, the apparatus 10 is shown surrounding an electronic device 40. The electronic device 40 may be held rigidly within apparatus 10. The electronic device may be held rigidly on its front side by the recessed lip 13. As shown in FIG. 4, the case 12 may have a plurality of extended inner edges 42 that may hold the electronic device 40 rigidly on its edges. As further shown in FIG. 4, the energy absorbing material 16 may fill the area between the recessed lip 13 and the extended inner edges 42. The energy absorbing material 16 may also fill the area between the extended inner edges 42. The energy absorbing material 16 may contact the bottom and each side of the electronic device 40 and the extended inner edges 42 may contact the edges of the electronic device 40 so that the electronic device 40 is completely encased on all sides except one. The exposed side, while protected as described above, may allow a user to conveniently interact with the electronic device 40.

The case 12 may preferably be made of thermoplastic polyurethane or any other known rugged flexible material known to one skilled in the art that can withstand the extreme stress described herein. The case 12 may be made from a plurality of layers to thermoplastic polyurethane or other rugged flexible material such that the encased electronic device is protected and the overall apparatus has a thin design.

Specifically, the case 12 may be tripled overmolded using thermoplastic polyurethanes with differing hardness to provide additional impact protection. The durometer scale measures the hardness of materials, specifically polymers, elastomers, and rubbers. The innermost thermoplastic polyurethane layer may be an 88 shore A durometer. The second thermoplastic polyurethane layer may also be an 88 shore A durometer. The outermost thermoplastic polyurethane layer may be a 94 shore A durometer. This differing in mold layers may increase the overall impact rating of the case 12.

The energy absorbing material 16 may be an energy absorbing foam or gel. Specifically, the energy absorbing material may preferably be or be similar to that of the Rogers Corporation's PORON® Urethane Foam (part no. 4790-79-15125-04). Specific information regarding properties relating to Rogers Corporation's PORON® Urethane Foam may be found in Rogers Corporation Poron® Urethane Foams “Shock Control Design Guide” and Rogers Corporation Poron® Urethane Foams “Handheld Shock Control Design Guide,” each of which can be found at http://www.rogerscorp.com and which are incorporated herein by reference in their entirety.

The energy absorbing material 16 may have properties of absorbing and spreading impact energy. Specifically, the energy absorbing material 16 may have a low deceleration value when impacted by an object. In addition, the case 12 combined with the energy absorbing material 16 may have a low deceleration value such that the case 12 and the energy absorbing material 16 act together in concert to safely slow down impact velocity of a falling object, absorb and distribute kinetic energy, and protect electronic devices from excessive drops. Of course, the energy absorbing material 16 and the case 12 may be made from other substances known to a person having ordinary skill in the art so long as the apparatus 10 can protect electronic devices from excessive drops.

It should be noted that the present invention describes, generally, a case having superior energy absorbing properties for a portable electronic phone, such as an iPhone, but the present invention should not be limited to the embodiment shown by the drawings and described herein. It should be apparent to one of ordinary skill in the art that the present invention may be useful for any case housing a portable electronic device, whether a smart phone, a tablet computer, such as an iPad or the like, or even a portable computer, such as a laptop computer.

It should be noted that various changes and modifications to the presently preferred embodiments described herein will be apparent to those skilled in the art. Such changes and modifications may be made without departing from the spirit and scope of the present invention and without diminishing its attendant advantages.

We claim:

1. An apparatus for protecting electronic devices comprising:
a case for surrounding an electronic device, wherein the case fits tightly around the electronic device, and
at least one section of energy absorbing foam or gel, wherein the case and the impact resistant material combine to protect the electronic device from excessive drops.
